(19) United States
(12) Patent Application Publication
(10) Pub. No.: US 2009/0129001 A1
(43) Pub. Date: May 21, 2009

(54) COMPUTER HOST HAVING TWO LAYERS INSIDE

(75) Inventors: Chen-Ho Wang, Taipei (TW); Yung-Chung Chen, Taipei (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: INVENTEC CORPORATION, Taipei (TW)

(21) Appl. No.: 11/943,658

(22) Filed: Nov. 21, 2007

(51) Int. Cl. G06F 1/16; H05K 5/00; H05K 7/00

(52) U.S. Cl. 361/679.02

(57) ABSTRACT

A computer host having two layers inside includes a chassis, a partition, a first circuit board, a second circuit board, and an electrical connecting device. The partition divides the interior of the chassis into a first accommodation space and a second accommodation space. The first circuit board and the second circuit board are disposed on two sides of the partition respectively, and are respectively located in the first accommodation space and the second accommodation space. The electrical connecting device is used to electrically connect the first circuit board and the second circuit board, so that the first and second circuit boards together form a complete electronic circuit system for the operation of the computer host.

### BACKGROUND OF THE INVENTION

1. Field of Invention

The present invention relates to a computer host structure, and more particularly to a computer host having two layers inside.

2. Related Art

As the circuit design of the computer host becomes progressively complicated, the number of the electronic elements on a circuit board (especially, a computer motherboard) is gradually increased, and thus a variety of problems may be encountered. After the increase of the number of the electronic elements, the electronic elements are arranged densely on the motherboard. Usually, electronic elements such as CPU, memory, graphic chip can only be disposed on one side of the circuit board, and the other side of the circuit board must be fixed onto the computer chassis. Under the circumstance of densely arranging electronic elements, the circuit layout becomes difficult to conduct. Meanwhile, the densely arranged electronic elements hinders the ventilation of the cooling airflow, and those electronic elements located in the downstream of the cooling airflow cannot receive the cool air that has not been heated by other elements, thus resulting in the difficulty in controlling the temperature.

In order to solve the problem caused by the increase of the number of the electronic elements, the simplest way is to expand the area of the circuit board, but the chassis of the computer host must be enlarged, and thus more space will be occupied. Another method is to adopt the server cluster architecture of the computer host, in which a plurality of computer hosts with simple structures is connected to become a single server cluster through the network or data transmission line. However, this method needs a plurality of computer hosts, so the cost is raised, and these computer hosts also take up more space.

### SUMMARY OF THE INVENTION

Accordingly, the present invention is directed to a computer host having two layers inside, so as to solve a variety of problems caused by the increase of the number of the electronic elements since the circuit design of the computer host becomes progressively complicated.

In order to achieve the above objective, a computer host having two layers inside including a chassis, a partition, a first circuit board, a second circuit board, and an electrical connecting device is provided. The partition is disposed in the chassis, for dividing the interior of the chassis into a first accommodation space and a second accommodation space. The first circuit board is disposed on one side of the partition, and is located in the first accommodation space. The second circuit board is disposed on the other side of the partition, and is located in the second accommodation space. The electrical connecting device is used to electrically connect the first circuit board and the second circuit board, such that the first and second circuit boards form a complete electronic circuit system for the operation of the computer host.

According to another embodiment of the present invention, a computer host having two layers inside, including a chassis, a partition, a first circuit board, and at least one CPU is provided. The partition has a hole and is disposed in the chassis, for dividing the interior of the chassis into a first accommodation space and a second accommodation space. The first circuit board is fixed onto one side of the partition, and is located in the first accommodation space. The CPU is disposed on the first circuit board at a side facing the partition, and is located in the hole. The heat generated by the CPU may be dissipated individually in the second accommodation space, thus effectively improving the heat dissipation effect.

The present invention has the following effect. After the interior of the chassis is divided into the first accommodation space and the second accommodation space, the circuit boards are respectively disposed in the two accommodation spaces. Thus, the total surface area of the circuit board is increased without increasing the size of the chassis, which facilitates the arrangement of the electronic elements. Or, as the two accommodation spaces are isolated from each other, different electronic elements are distributed in different accommodation spaces for cooling, thereby solving the problem of undesirable air-cooling effect resulting from the large number of electronic elements.

The features and advantages of the present invention will be described in detail in the following embodiments. Those skilled in the arts can easily understand and implement the content of the present invention. Furthermore, the relative objectives and advantages of the present invention are apparent to those skilled in the arts with reference to the content disclosed in the specification, claims, and drawings.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 is an exploded three-dimensional view of a first embodiment of the present invention;

FIG. 2 is a schematic cross-sectional view of the first embodiment of the present invention;

FIG. 3 is a schematic cross-sectional view of a second embodiment of the present invention;

FIG. 4 is an exploded three-dimensional view of a third embodiment of the present invention;

FIG. 5 is a schematic cross-sectional view of the third embodiment of the present invention; and

FIG. 6 is a schematic cross-sectional view of a fourth embodiment of the present invention.

### DETAILED DESCRIPTION OF THE INVENTION

The objectives, structures, features, and functions of the present invention will be illustrated in detail below in the accompanying embodiments.

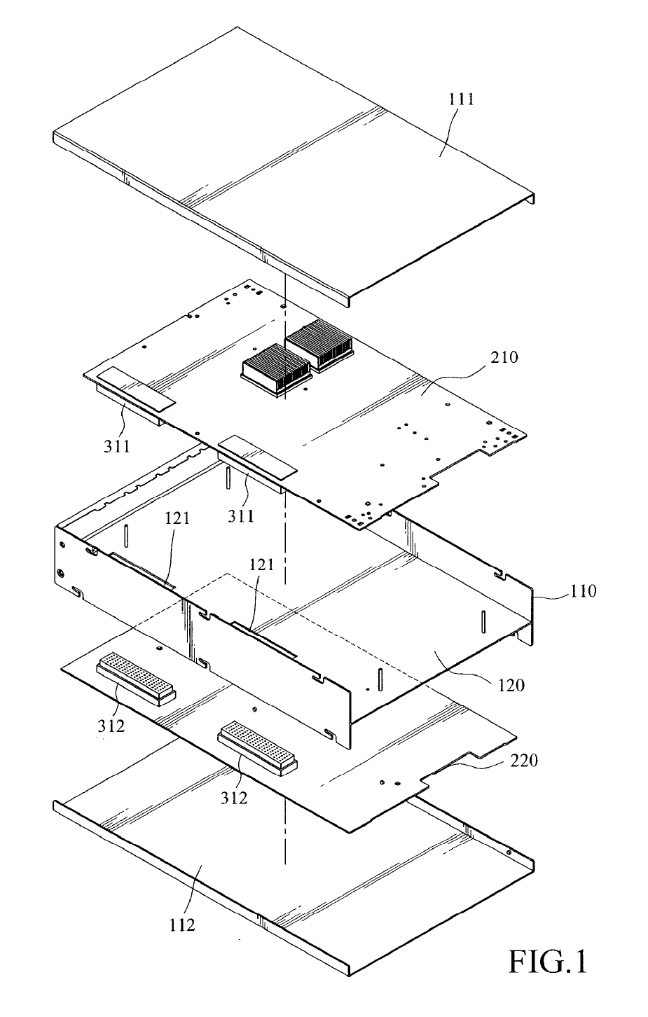

Referring to FIG. 1, a computer host having two layers inside according to a first embodiment of the present invention is shown. The computer host having two layers inside may be a separate desk-top computer, server, or a host of a server architecture mounted within a server chassis. The computer host having two layers inside includes a chassis 110, a partition 120, a first circuit board 210, a second circuit board 220, and two electrical connecting devices.

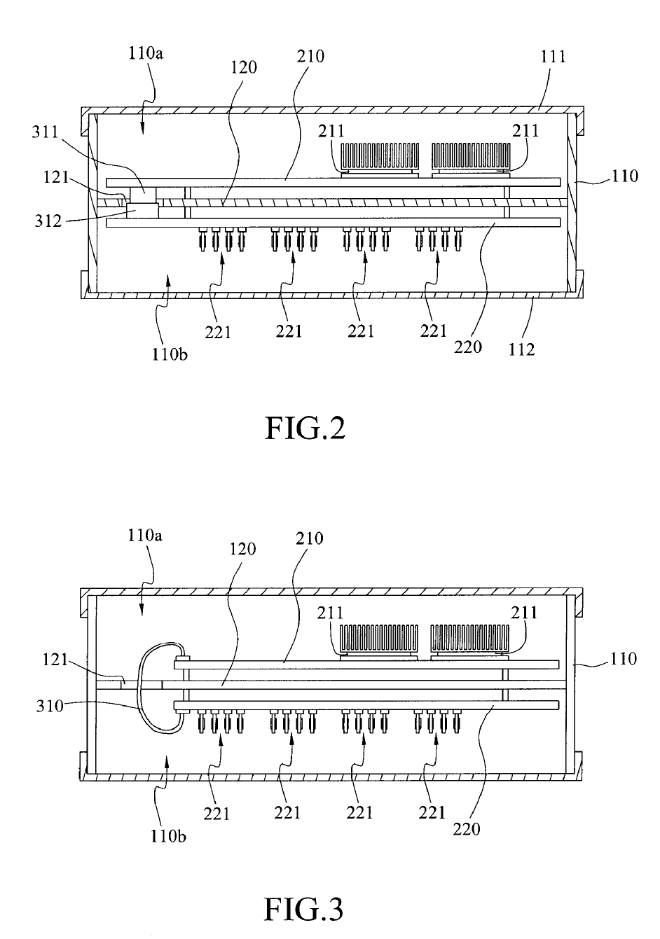

Referring to FIGS. 1 and 2, the chassis 110 accommodates the first circuit board 210, the second circuit board 220, the electrical connecting devices, and other electronic elements that constitute the computer host having two layers inside. The partition 120 is disposed in the chassis 110, for dividing the interior of the chassis 110 into a first accommodation space 110a and a second accommodation space 110b. The partition 120 has two perforations 121, for allowing the electrical connecting devices to pass through. Moreover, the chassis 110 further includes an upper cover 111 and a lower cover 112, which are detachably fixed onto the top surface and bottom surface of the chassis 110 respectively, for enclosing the first accommodation space 110a and the second accommodation space 110b. Or, the upper cover 111 and the lower cover 112 may be detached separately, so that the first accommodation space 110a and the second accommodation space 110b are open to the outside.

Referring to FIGS. 1 and 2 again, the first circuit board 210 is disposed on an upper side of the partition 120, and located in the first accommodation space 110a. The second circuit board 220 is disposed on a lower side of the partition 120, and located in the second accommodation space 110b. The electrical connecting devices each include a first electrical connector 311 and a second electrical connector 312. The first electrical connector 311 is disposed on the first circuit board 210, and the second electrical connector 312 is disposed on the second circuit board 220. When the first circuit board 210 and the second circuit board 220 are respectively fixed onto the upper and lower sides of the partition 120, the first electrical connector 311 of each electrical connecting device passes through a corresponding perforation 121 to be electrically connected to a corresponding second electrical connector 312. Thus, the first circuit board 210 and the second circuit board 220 are electrically connected, such that the first circuit board 210 and the second circuit board 220 form a complete electronic circuit system. For example, in this embodiment, high heat-generating electronic chips such as a CPU 211, a logic chip set (not shown), a graphic chip set (not shown) in the electronic circuit system are disposed on the first circuit board 210. A memory module 221 that also produces high heat is disposed on the second circuit board 220, since the main electronic elements have already been disposed on the first circuit board 210. Thus, the area of the second circuit board 220 can be fully utilized to dispose the memory module 221. In this manner, on the same area (the cross-sectional area of the chassis 110), more electronic elements can be disposed as compared with the conventional architecture of the computer host. Moreover, the electronic elements on the first circuit board 210 and the second circuit board 220 are respectively located in the first accommodation space 110a and the second accommodation space 110b, so they are cooled down by individual air-cooling systems respectively, thus eliminating the interference of the electronic elements to the air-cooling system.

In the present invention, two circuit boards 210, 220 are disposed in the same chassis 110. The circuit boards 210, 220 respectively provide a part of the functions of a complete electronic circuit system, and are electrically connected through the electrical connecting devices so as to form a single electronic circuit system. In this embodiment, each electrical connecting device includes a first electrical connector 311 and a second electrical connector 312. However, the electrical connecting devices are used for electrically connecting the two circuit boards, and the configuration thereof is not limited to the first embodiment.

Referring to FIG. 3, a computer host having two layers inside according to a second embodiment of the present invention is shown. The computer host includes a chassis 110, a partition 120, a first circuit board 210, a second circuit board 220, and at least one electrical connecting device 310. The partition 120 is disposed in the chassis 110, for dividing the interior of the chassis 110 into a first accommodation space 110a and a second accommodation space 110b. The partition 120 has at least one perforation 121. The first circuit board 210 and the second circuit board 220 are respectively disposed on an upper side and a lower side of the partition 120, and located in the first accommodation space 110a and the second accommodation space 110b. The electrical connecting device 310 is a signal line passing through the perforation 121 of the partition 120. The two ends of the electrical connecting device 310 are respectively connected to the first circuit board 210 and the second circuit board 220 to electrically connect the first circuit board 210 to the second circuit board 220 so as to form a complete electronic circuit system.

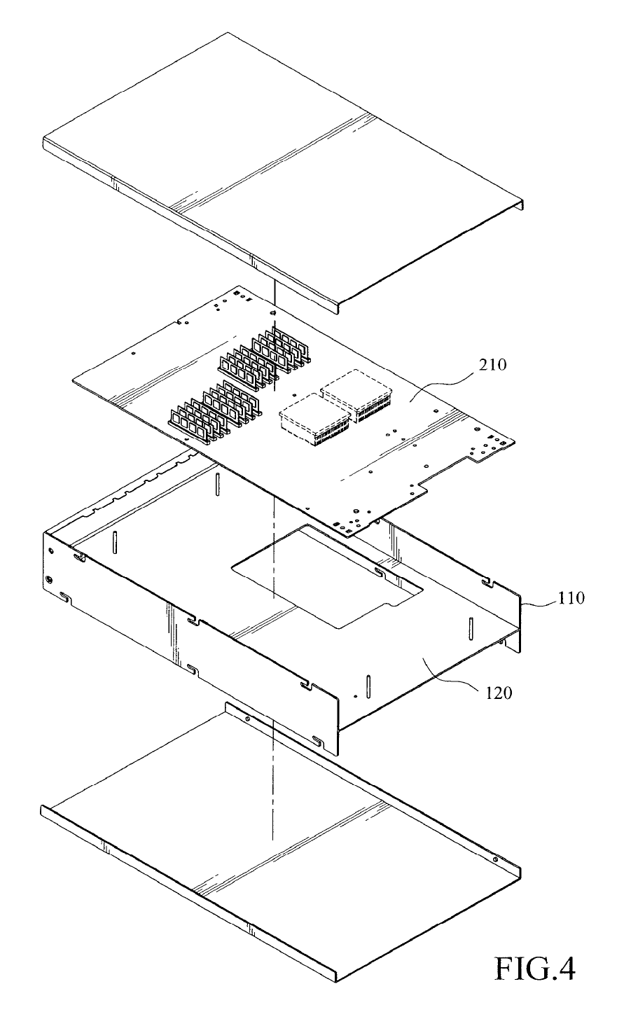

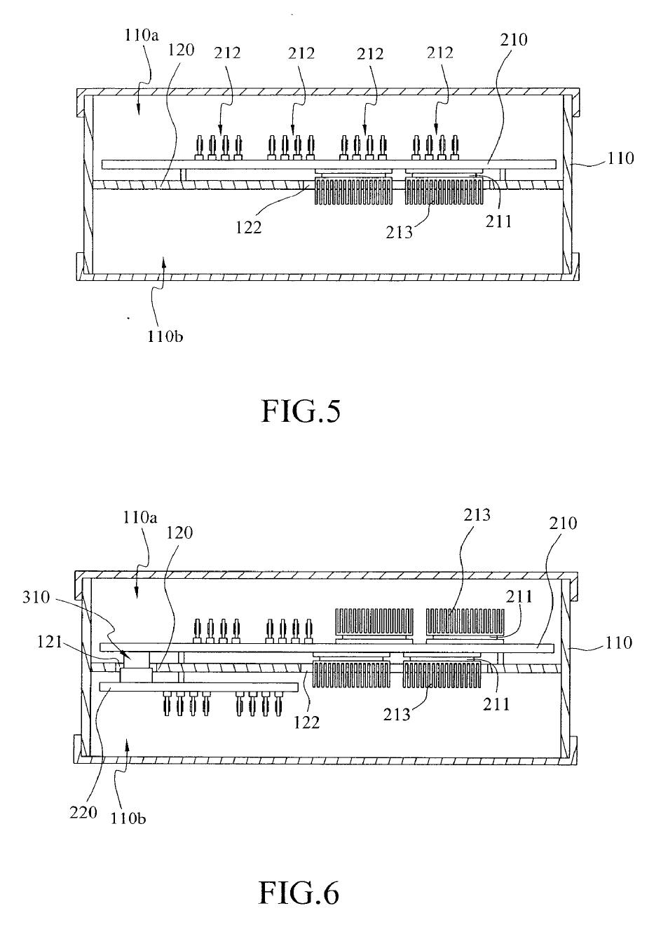

Referring to FIGS. 4 and 5, a computer host having two layers inside according to a third embodiment of the present invention is shown. The computer host includes a chassis 110, a partition 120, and a first circuit board 210. The partition 120 is disposed in the chassis 110, for dividing the interior of the chassis into a first accommodation space 110a and a second accommodation space 110b. The partition 120 has a hole 122. The first circuit board 210 is fixed onto an upper side of the partition 120, and located in the first accommodation space 110a. Electronic elements, for example, a memory module 212, a logic chip set (not shown), a graphic chip (not shown) excluding the CPU 211 may be disposed on the first circuit board 210 at a side far from the partition 120. The CPU 211 may be disposed on the first circuit board 210 at a side facing the partition 120, and located in the hole 122. A heatsink device 213 is disposed on the CPU 211, and is located in the second accommodation space 110b through the hole 122. In this manner, electronic elements excluding the CPU 211 may be cooled down by a cooling airflow passing through the first accommodation space 110a. The CPU 211 is cooled down solely by a cooling airflow passing through the second accommodation space 110b. The two airflows are isolated by the partition 120 to avoid interference, thus ensuring an optimal cooling effect.

Referring to FIG. 6, a computer host having two layers inside according to a fourth embodiment of the present invention is shown. The computer host includes a chassis 110, a partition 120, a first circuit board 210, and a second circuit board 220. The partition 120 is disposed in the chassis 110, for dividing the interior of the chassis into a first accommodation space 110a and a second accommodation space 110b. The partition 120 has a hole 122. The first circuit board 210 is fixed onto an upper side of the partition 120, and located in the first accommodation space 110a. At least one CPU 211 is disposed on two sides of the first circuit board 210 respectively, in which one CPU 211 is disposed on the first circuit board 210 at a side facing the partition 120, and is located in the hole 122. A heatsink device 213 disposed on the CPU 211 pass through the hole 122 and protrudes into the second accommodation space 110b. Another CPU 211 is disposed on the first circuit board 210 at a side far away from the partition 120, such that a heatsink device 213 disposed on the CPU 211 is located in the first accommodation space 110a.

The area of the second circuit board 220 is much smaller than the cross-sectional area of the chassis 110 or the area of the partition. The second circuit board 220 is disposed on a lower side of the partition 120, and does not block the hole 122, such that the heatsink device 213 protrudes into the second accommodation space 110b. The partition 120 further has a perforation 121, for allowing an electrical connecting device 310 to pass through so as to electrically connect the first circuit board 210 and the second circuit board 220. Thus, the first circuit board 210 and the second circuit board 220 form a complete electronic circuit system. When a plurality of CPUs is used, the CPUs 211 may be respectively disposed on two sides of the first circuit board 210. Thus, the CPUs 211 are distributed in the first accommodation space 110a and the second accommodation space 110b, and are cooled down by different cooling airflows, thereby improving the cooling effect.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A computer host having two layers inside, comprising:
a chassis;
a partition, disposed in the chassis, for dividing an interior of the chassis into a first accommodation space and a second accommodation space;
a first circuit board, disposed on one side of the partition, and located in the first accommodation space;
a second circuit board, disposed on the other side of the partition, and located in the second accommodation space; and
an electrical connecting device, for electrically connecting the first circuit board and the second circuit board.

2. The computer host having two layers inside as claimed in claim 1, wherein the partition has at least one perforation, and the electrical connecting device passes through the perforation.

3. The computer host having two layers inside as claimed in claim 2, wherein the electrical connecting device comprises a first electrical connector and a second electrical connector, the first electrical connector is disposed on the first circuit board, and the second electrical connector is disposed on the second circuit board, wherein the first electrical connector passes through the perforation to be electrically connected to the second electrical connector.

4. The computer host having two layers inside as claimed in claim 2, wherein the electrical connecting device is a signal line with two ends respectively connected to the first circuit board and the second circuit board, and the signal line passes through the perforation.

5. A computer host having two layers inside, comprising:
a chassis;
a partition, having a hole, and disposed in the chassis, for dividing an interior of the chassis into a first accommodation space and a second accommodation space;
a first circuit board, fixed onto one side of the partition, and located in the first accommodation space; and
at least one CPU, disposed on the first circuit board at a side facing the partition, and located in the hole.

6. The computer host having two layers inside as claimed in claim 5, further comprising a second circuit board disposed on the other side of the partition without blocking the hole, wherein the second circuit board is electrically connected to the first circuit board.

7. The computer host having two layers inside as claimed in claim 6, wherein the partition has a perforation for an electrical connecting device to pass through, so as to electrically connect the first circuit board and the second circuit board.

8. The computer host having two layers inside as claimed in claim 5, further comprising at least another CPU disposed on the first circuit board at a side far away from the partition.

9. The computer host having two layers inside as claimed in claim 5, further comprising a heatsink device disposed on the CPU, and protruding into the second accommodation space through the hole.
